(19) United States
(12) Patent Application Publication
(10) Pub. No.: US 2025/0176104 A1
(43) Pub. Date: May 29, 2025

(54) PRINTED CIRCUIT BOARD AND SEMICONDUCTOR PACKAGE INCLUDING THE SAME

(71) Applicant: SAMSUNG ELECTRONICS CO., LTD., Suwon-si (KR)

(72) Inventors: Sunchul Kim, Suwon-si (KR); Yonghyun Kim, Suwon-si (KR); Kwangbok Woo, Suwon-si (KR); Juhyung Lee, Suwon-si (KR)

(21) Appl. No.: 18/887,302

(22) Filed: Sep. 17, 2024

(30) Foreign Application Priority Data
Nov. 23, 2023 (KR) 10-2023-0164847

(51) Int. Cl. H05K 1/11; H01L 23/00; H01L 23/498

(52) U.S. Cl. CPC H05K 1/111; H01L 23/49838; H01L 24/05; H01L 24/13; H01L 24/16; H01L 24/17; H01L 24/32; H01L 24/73; H01L 2224/0401; H01L 2224/05558; H01L 2224/05566; H01L 2224/13082; H01L 2224/16227; H01L 2224/17517

(57) ABSTRACT

A printed circuit board includes a substrate base, a plurality of upper pads on an upper surface of the substrate base, a plurality of lower connection pads beneath a lower surface of the substrate base, and a substrate wiring structure. The plurality of upper pads includes a plurality of upper connection pads and an upper monitoring pad. The substrate wiring structure electrically connects the plurality of upper connection pads to the plurality of lower connection pads. The upper monitoring pad includes a base pad portion having the same planar shape as each of the plurality of upper connection pads and a protrusion portion extending in a horizontal direction from the base pad portion. The protrusion portion of the upper monitoring pad enables easy detection of a proper connection between the substrate base and a semiconductor device mounted on the printed circuit board.

### CROSS-REFERENCE TO RELATED APPLICATION

This application claims priority under 35 U.S.C. § 119 to Korean Patent Application No. 10-2023-0164847, filed on Nov. 23, 2023, in the Korean Intellectual Property Office, the disclosure of which is incorporated by reference herein in its entirety.

### BACKGROUND

Along with the rapid development of the electronics industry and demands of users, electronic devices have been gradually miniaturized with high performance. Therefore, along with the miniaturization and high performance of semiconductor packages included in electronic devices, a semiconductor package including a semiconductor chip flip-chip-bonded to a printed circuit board has been developed.

### SUMMARY

This disclosure relates to a printed circuit board and a semiconductor package including the same, and more particularly, to a printed circuit board for flip chip bonding and a semiconductor package including the printed circuit board and a flip-chip-bonded semiconductor chip. The printed circuit board and semiconductor package may have improved electrical connection reliability.

In an example, there is provided a printed circuit board including a substrate base, a plurality of upper pads on an upper surface of the substrate base and including a plurality of upper connection pads and at least one upper monitoring pad, a plurality of lower connection pads beneath a lower surface of the substrate base, and a substrate wiring structure electrically connecting the plurality of upper connection pads to the plurality of lower connection pads, wherein the at least one upper monitoring pad includes a base pad portion having the same planar shape as each of the plurality of upper connection pads and a protrusion portion extending in a horizontal direction from the base pad portion.

In an example, there is provided a semiconductor package including a printed circuit board including a substrate base, an upper solder resist layer covering an upper surface of the substrate base, a plurality of upper pads on the upper surface of the substrate base, including a plurality of upper connection pads and at least one upper monitoring pad, and not covered by the upper solder resist layer, a plurality of lower connection pads beneath a lower surface of the substrate base, and a substrate wiring structure electrically connecting the plurality of upper connection pads to the plurality of lower connection pads, respectively, a semiconductor chip including a semiconductor substrate and a plurality of chip pads beneath a lower surface of the semiconductor substrate and including a plurality of chip connection pads and at least one chip dummy pad and attached to the printed circuit board such that the plurality of chip pads face the printed circuit board, and a plurality of chip terminals including a plurality of chip connection terminals between the plurality of upper connection pads and the plurality of chip connection pads and at least one chip dummy terminal between the at least one upper monitoring pad and the at least one chip dummy pad, wherein the at least one upper monitoring pad includes a base pad portion having the same planar shape as each of the plurality of upper connection pads and a protrusion portion extending in a horizontal direction from the base pad portion.

In an example, there is provided a semiconductor package including a printed circuit board including a substrate base, an upper solder resist layer covering an upper surface of the substrate base, a lower solder resist layer covering a lower surface of the substrate base, a plurality of upper pads on the upper surface of the substrate base, including a plurality of upper connection pads and a plurality of upper monitoring pads, and uncovered by the lower solder resist layer, a plurality of lower connection pads beneath the lower surface of the substrate base and not covered by the upper solder resist layer, and a substrate wiring structure electrically connecting the plurality of upper connection pads to the plurality of lower connection pads, a semiconductor chip which includes a semiconductor substrate having a semiconductor device and a plurality of chip pads beneath a lower surface of the semiconductor substrate and including a plurality of chip connection pads electrically connected to the semiconductor device and a plurality of chip dummy pads electrically isolated from the semiconductor device, the semiconductor chip being attached to the printed circuit board such that the plurality of chip pads face the printed circuit board, and a plurality of chip terminals including a plurality of chip connection terminals between the plurality of upper connection pads and the plurality of chip connection pads and a plurality of chip dummy terminals between the plurality of upper monitoring pads and the plurality of chip dummy pads, each of the plurality of chip connection terminals and the plurality of chip dummy terminals including an under bump metal (UBM) layer covering at least a portion of a lower surface of a chip pad, a conductive pillar attached beneath the chip pad and the UBM layer, and a conductive cap covering a lower surface of the conductive pillar and fully covering upper surfaces of the plurality of chip pads, wherein each of the plurality of upper monitoring pads includes a base pad portion having the same planar shape as each of the plurality of upper connection pads and a plurality of protrusion portions extending in a horizontal direction from the base pad portion.

### BRIEF DESCRIPTION OF THE DRAWINGS

Embodiments will be more clearly understood from the following detailed description taken in conjunction with the accompanying drawings in which:

FIG. 1 is a cross-sectional view of an example semiconductor package including a printed circuit board;

FIG. 2A is a top view illustrating an upper connection pad of an example printed circuit board, and FIG. 2B is a top view illustrating an upper monitoring pad of an example printed circuit board;

FIGS. 3A to 3D are top views and cross-sectional views illustrating an inspection result of a chip connection terminal connected to an upper connection pad and a chip dummy terminal connected to an upper monitoring pad in an example semiconductor package including a printed circuit board;

FIGS. 4A to 4D are top views and cross-sectional views illustrating an inspection result of a chip connection terminal on an upper connection pad and a chip dummy terminal on an upper monitoring pad in an example semiconductor package including a printed circuit board;

FIGS. 5A to 5E are top views illustrating upper monitoring pads of an example printed circuit board;

FIGS. 6A to 6C are top views illustrating example printed circuit boards;

FIGS. 7A to 7E are top views illustrating example printed circuit boards; and

FIGS. 8A and 8B are top views illustrating example printed circuit boards.

### DETAILED DESCRIPTION

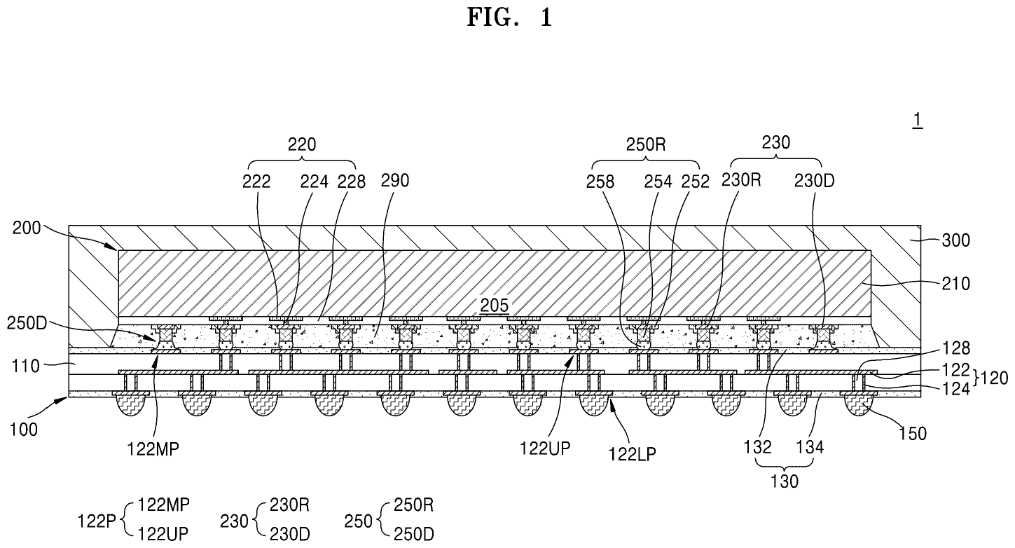

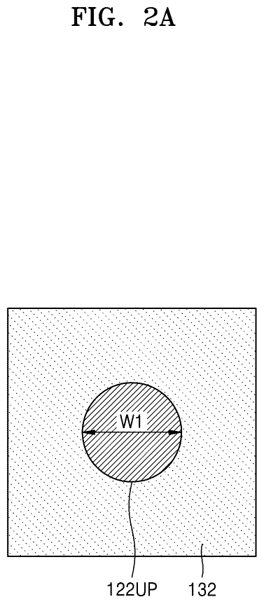

FIG. 1 is a cross-sectional view of an example semiconductor package 1 including a printed circuit board 100.

Referring to FIG. 1, the semiconductor package 1 may include the printed circuit board 100 and at least one semiconductor chip 200 attached onto the printed circuit board 100.

For example, the printed circuit board 100 may be a double-sided printed circuit board or a multi-layer printed circuit board. The printed circuit board 100 may include at least one substrate base 110 and a substrate wiring structure 120.

The at least one substrate base 110 may include at least one material selected from among a phenol resin, an epoxy resin, and polyimide. For example, the at least one substrate base 110 may include at least one material selected from among flame retardant 4 (FR-4), tetrafunctional epoxy, polyphenylene ether, epoxy/polyphenylene oxide, bismaleimide triazine (BT), Thermount, cyanate ester, polyimide, and a liquid crystal polymer.

In some implementations, the printed circuit board 100 may include a plurality of substrate bases 110 that are stacked. When the printed circuit board 100 includes a plurality of substrate bases 110 that are stacked, the plurality of substrate bases 110 may include a core layer and at least one prepreg layer stacked on each of the upper and lower surfaces of the core layer. In some implementations, each of the core layer and the at least one prepreg layer may include the same material. The thickness of each of the at least one prepreg layer may be less than the thickness of the core layer.

In the specification, the at least one substrate base 110 or the plurality of substrate bases 110 may indicate all the substrate bases 110 included in the printed circuit board 100, i.e., indicate one substrate base 110 if the printed circuit board 100 includes the one substrate base 110 and indicate a structure with all of two or more substrate bases 110 that are stacked if the printed circuit board 100 includes the two or more substrate bases 110 that are stacked, and the upper surface and the lower surface of the at least one substrate base 110 or the plurality of substrate bases 110 may indicate the upper surface and the lower surface of all the substrate bases 110 included in the printed circuit board 100.

The substrate wiring structure 120 may include a plurality of substrate wiring patterns 122 on the upper surface and the lower surface or in the inside of the at least one substrate base 110 and extending in a horizontal direction and a plurality of substrate via patterns 124 extending in the vertical direction by penetrating at least a portion of the at least one substrate base 110, each substrate via pattern 124 electrically connecting between two substrate wiring patterns 122 at different vertical levels among the plurality of substrate wiring patterns 122. In some implementations, the printed circuit board 100 may include the plurality of substrate bases 110 that are stacked and the plurality of substrate wiring patterns 122 may be on the upper surfaces and the lower surfaces of the plurality of substrate bases 110. For example, some of the plurality of substrate wiring patterns 122 may be between two substrate bases 110 adjacent to each other in the vertical direction among the plurality of substrate bases 110.

The substrate wiring structure 120 may include copper (Cu) or an alloy including Cu. In some implementations, a substrate via pattern 124 may be formed to fill a portion of a via through hole while covering the inner wall of the via through hole that penetrates a substrate base 110 and a via filling insulating layer 128 may fill the via through hole while covering the substrate via pattern 124. For example, the via through hole may be fully filled with the substrate via pattern 124 and the via filling insulating layer 128.

The printed circuit board 100 may further include a solder resist layer 130 covering the upper surface and the lower surface of the at least one substrate base 110. The solder resist layer 130 may include an upper solder resist layer 132 covering the upper surface of the at least one substrate base 110 and a lower solder resist layer 134 covering the lower surface of the at least one substrate base 110.

Portions of substrate wiring patterns 122 on the upper surface of the at least one substrate base 110 may be a plurality of upper pads 122P, respectively. For example, portions of substrate wiring patterns 122 at the highest vertical level may be the plurality of upper pads 122P, respectively. The upper solder resist layer 132 may cover the side surfaces of the substrate wiring patterns 122 on the upper surface of the at least one substrate base 110. Portions of the substrate wiring patterns 122 on the upper surface of the at least one substrate base 110 may not be covered by the upper solder resist layer 132. In some implementations, the upper solder resist layer 132 may cover only a portion of the upper surfaces of the plurality of upper pads 122P. For example, the upper solder resist layer 132 may cover a portion of the upper surface of each of the substrate wiring patterns 122. The uncovered portion of the substrate wiring patterns 122 on the upper surface of the substrate base 110 forms the plurality of upper pads 122P. A plurality of chip terminals 250 may be attached to the plurality of upper pads 122P, respectively.

The plurality of upper pads 122P may include a plurality of upper connection pads 122UP and at least one upper monitoring pad 122MP. The plurality of chip terminals 250 may include a plurality of chip connection terminals 250R and at least one chip dummy terminal 250D. The plurality of chip connection terminals 250R may be attached to the plurality of upper connection pads 122UP, respectively, and the at least one chip dummy terminal 250D may be attached to the at least one upper monitoring pad 122MP.

In some implementations, the plurality of chip terminals 250 may fully cover surfaces (e.g., the upper surfaces of the plurality of upper pads 122P) which are not covered by the upper solder resist layer 132. In some implementations, the plurality of chip connection terminals 250R may fully cover the upper surfaces of the plurality of upper connection pads 122UP, respectively, and the at least one chip dummy terminal 250D may fully cover the upper surface of the at least one upper monitoring pad 122MP. In some implementations, the plurality of chip terminals 250 may not cover portions of the upper surfaces of the plurality of upper pads 122P, which are not covered by the upper solder resist layer 132, respectively.

Portions of substrate wiring patterns 122 beneath the lower surface of the at least one substrate base 110 may be a plurality of lower connection pads 122LP, respectively. For example, portions of substrate wiring patterns 122 at the lowest vertical level may be the plurality of lower connection pads 122LP, respectively. The lower solder resist layer 134 may cover the side surfaces of the substrate wiring patterns 122 beneath the lower surface of the at least one substrate base 110. The portions of the substrate wiring patterns 122 beneath the lower surface of the at least one substrate base 110 may not be covered by the lower solder resist layer 134. In some implementations, the lower solder resist layer 134 may not cover the lower surfaces of the plurality of lower connection pads 122LP. For example, the lower solder resist layer 134 may cover a portion of the lower surface of each of the substrate wiring patterns 122, each including a lower connection pad 122LP, but not cover the other portion of the lower surface of each of the substrate wiring patterns 122. The other portions of the substrate wiring patterns 122, which are not covered by the lower solder resist layer 134, may be the plurality of lower connection pads 122LP. A plurality of package connection terminals 150 may be attached to the plurality of lower connection pads 122LP, respectively. In some implementations, the plurality of package connection terminals 150 may fully cover the surfaces (e.g., the lower surfaces, of the plurality of lower connection pads 122LP) which are not covered by the lower solder resist layer 134, respectively.

Alternatively, portions not covered by the upper solder resist layer 132 among conductive material layers on the upper surface of the at least one substrate base 110 may be referred to as the plurality of upper pads 122P. Those portions connected to the plurality of upper pads 122P and covered by the upper solder resist layer 132 may be referred to as top substrate base patterns 122 among the plurality of substrate wiring patterns 122. Portions not covered by the lower solder resist layer 134 among conductive material layers beneath the lower surface of the at least one substrate base 110 may be referred to as the plurality of lower connection pads 122LP. Only those portions connected to the plurality of lower connection pads 122LP and covered by the lower solder resist layer 134 may be referred to as bottom substrate base patterns 122 among the plurality of substrate wiring patterns 122. That is, the substrate wiring structure 120 including the plurality of substrate wiring patterns 122 and the plurality of substrate via patterns 124 may electrically connect the plurality of upper connection pads 122UP to the plurality of lower connection pads 122LP.

A semiconductor chip 200 may include a semiconductor substrate 210, a wiring layer 220, and a plurality of chip pads 230. The semiconductor substrate 210 may have an active surface and an inactive surface that are opposite to each other. A semiconductor device 205 may be formed on the active surface of the semiconductor substrate 210. The wiring layer 220 may be on the active surface of the semiconductor substrate 210. For example, the wiring layer 220 may cover the active surface of the semiconductor substrate 210. The plurality of chip pads 230 may be on the wiring layer 220. For example, the plurality of chip pads 230 may be beneath the lower surface of the wiring layer 220. The semiconductor chip 200 may have a first surface and a second surface that are opposite to each other. The plurality of chip pads 230 may be on the first surface of the semiconductor chip 200. The second surface of the semiconductor chip 200 may be the inactive surface of the semiconductor substrate 210. The semiconductor chip 200 may be attached onto the printed circuit board 100 by flip chip bonding such that the first surface of the semiconductor chip 200 faces the printed circuit board 100. For example, the semiconductor chip 200 may be attached onto the printed circuit board 100 such that the plurality of chip pads 230 face the printed circuit board 100.

The semiconductor substrate 210 may include a semiconductor material, e.g., a group IV semiconductor material, a group III-V semiconductor material, a group II-VI semiconductor material, or a group II-VI oxide semiconductor material. The semiconductor substrate 210 may include a conductive region, (e.g., an impurity-doped well). The semiconductor substrate 210 may have various device isolation structures, such as a shallow trench isolation (STI) structure.

The semiconductor device 205 including a plurality of individual devices of various types may be formed on the active surface of the semiconductor substrate 210. The plurality of individual devices may include various microelectronic devices, for example, a metal-oxide-semiconductor field effect transistor (MOSFET), such as a complementary metal-oxide-semiconductor (CMOS) transistor, a system large scale integration (LSI), an active device, a passive device, and the like. The plurality of individual devices may be electrically connected to the conductive region of the semiconductor substrate 210. The semiconductor device 205 may further include a conductive wiring or a conductive plug electrically connecting at least two of the plurality of individual devices or electrically connecting the plurality of individual devices to the conductive region of the semiconductor substrate 210. In addition, each of the plurality of individual devices may be electrically isolated from other neighboring individual devices by an insulating layer. The semiconductor device 205 may be a logic device or a memory device. The memory device may be a volatile or nonvolatile memory device.

The wiring layer 220 may be on the active surface of the semiconductor substrate 210. The wiring layer 220 may include a plurality of wiring patterns 222, a plurality of via patterns 224, and an inter-wiring insulating layer 228. The plurality of via patterns 224 may be connected to the upper surfaces and/or the lower surfaces of the plurality of wiring patterns 222. In some implementations, the plurality of wiring patterns 222 may be spaced apart from each other at different vertical levels and each of the plurality of via patterns 224 may connect between wiring patterns 222 at different vertical levels. The plurality of wiring patterns 222 and the plurality of via patterns 224 may be electrically connected to the semiconductor device 205. The inter-wiring insulating layer 228 may surround the plurality of wiring patterns 222 and the plurality of via patterns 224. Each of the plurality of wiring patterns 222 and the plurality of via patterns 224 may include a metal, such as copper (Cu), aluminum (Al), tungsten (W), silver (Ag), gold (Au), titanium (Ti), or tantalum (Ta), or a metal nitride, such as titanium nitride (TiN) or tantalum nitride (TaN), or a combination thereof. The inter-wiring insulating layer 228 may include an insulating material including silicon oxide, silicon nitride, a low-k material, or a combination thereof. The low-k material has a dielectric constant lower than that of silicon oxide.

The plurality of chip pads 230 may include a plurality of chip connection pads 230R and at least one chip dummy pad 230D. The plurality of chip terminals 250 may be connected to the plurality of chip pads 230, respectively. The plurality of chip terminals 250 may be between the plurality of chip pads 230 and the plurality of upper pads 122P, respectively, and electrically connect the at least one semiconductor chip 200 to the printed circuit board 100. The plurality of chip connection terminals 250R may be connected to the plurality of chip connection pads 230R, respectively, and the at least one chip dummy terminal 250D may be connected to the at least one chip dummy pad 230D. The plurality of chip connection terminals 250R may be between the plurality of chip connection pads 230R and the plurality of upper connection pads 122UP, respectively, and the at least one chip dummy terminal 250D may be between the at least one chip dummy pad 230D and the at least one upper monitoring pad 122MP. The plurality of chip connection pads 230R may be electrically connected to the semiconductor device 205. The plurality of chip connection pads 230R may be electrically connected to the wiring layer 220. For example, each of the plurality of chip connection pads 230R may be electrically connected to the semiconductor device 205 via the plurality of wiring patterns 222 and the plurality of via patterns 224. The at least one chip dummy pad 230D may not be electrically connected to the semiconductor device 205. In some implementations, the at least one chip dummy pad 230D may not be electrically connected to the wiring layer 220. For example, the at least one chip dummy pad 230D may not be electrically connected to the plurality of wiring patterns 222 and the plurality of via patterns 224.

In some implementations, the at least one semiconductor chip 200 may include a logic device. For example, the at least one semiconductor chip 200 may be a central processing unit (CPU) chip, a graphics processing unit (GPU) chip, or an application processor (AP) chip. In some implementations, the at least one semiconductor chip 200 may be a memory semiconductor chip including a memory device. For example, the memory device may be a nonvolatile memory device, such as flash memory, phase-change random access memory (PRAM), magnetoresistive random access memory (MRAM), ferroelectric random access memory (FeRAM), or resistive random access memory (RRAM). The flash memory may be, for example, NAND flash memory or V-NAND flash memory. In some implementations, the memory device may be a volatile memory device, such as dynamic random access memory (DRAM) or static random access memory (SRAM). In some implementations, when the semiconductor package 1 includes a plurality of semiconductor chips 200, at least one of the plurality of semiconductor chips 200 may be a CPU chip, a GPU chip, or an AP chip and at least one other of the plurality of semiconductor chips 200 may be a memory semiconductor chip including a memory device.

The semiconductor package 1 may further include, on the printed circuit board 100, a molding layer 300 surrounding the at least one semiconductor chip 200 while covering the upper surface of the printed circuit board 100. For example, the molding layer 300 may be a molding member including an epoxy mold compound (EMC). In some implementations, the molding layer 300 may cover the side surfaces and the upper surface of the at least one semiconductor chip 200. In another embodiment, the molding layer 300 may cover the side surfaces of the at least one semiconductor chip 200 but not cover the upper surface of the at least one semiconductor chip 200. When the molding layer 300 does not cover the upper surface of the at least one semiconductor chip 200, the semiconductor package 1 may further include a heat-dissipating member covering the upper surface of the at least one semiconductor chip 200. The heat-dissipating member may include a heat-dissipating plate, such as a heat slug or a heat sink. In addition, the semiconductor package 1 may further include a thermal interface material (TIM) between the heat-dissipating member and the at least one semiconductor chip 200. The TIM may be formed of a paste, a film, or the like.

In some implementations, an underfill layer 290 surrounding the plurality of chip terminals 250 and filling between the printed circuit board 100 and the at least one semiconductor chip 200 may be between the printed circuit board 100 and the at least one semiconductor chip 200. The underfill layer 290 may include a resin. For example, the underfill layer 290 may be formed of an epoxy resin by a capillary under-fill method. In some implementations, the underfill layer 290 may be mixed with a filler including, for example, silica.

In some implementations, the semiconductor package 1 may not include the underfill layer 290, wherein the molding layer 300 may be formed of a molded under fill (MUF) surrounding the plurality of chip terminals 250 and between the printed circuit board 100 and the at least one semiconductor chip 200.

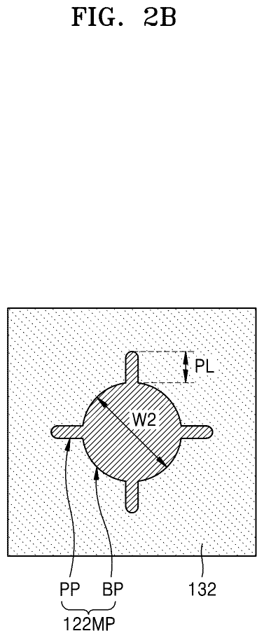

FIG. 2A is a top view illustrating an upper connection pad of a printed circuit board, and FIG. 2B is a top view illustrating an upper monitoring pad of the printed circuit board.

Referring to FIGS. 1, 2A, and 2B, the printed circuit board 100 may include the at least one substrate base 110, the substrate wiring structure 120, and the solder resist layer 130. The substrate wiring structure 120 may include the plurality of substrate wiring patterns 122 on the upper surface and the lower surface or in the inside of the at least one substrate base 110 and extending in the horizontal direction and the plurality of substrate via patterns 124 extending in the vertical direction by penetrating at least a portion of the at least one substrate base 110, each substrate via pattern 124 electrically connecting between two substrate wiring patterns 122 located at different vertical levels among the plurality of substrate wiring patterns 122. The solder resist layer 130 may include the upper solder resist layer 132 covering the upper surface of the at least one substrate base 110 and the lower solder resist layer 134 covering the lower surface of the at least one substrate base 110.

Portions of substrate wiring patterns 122 on the upper surface of the at least one substrate base 110 may be the plurality of upper pads 122P, respectively. For example, portions of substrate wiring patterns 122 at the highest vertical level may be the plurality of upper pads 122P, respectively. The plurality of upper pads 122P may not be covered by the upper solder resist layer 132. The plurality of upper pads 122P may include the plurality of upper connection pads 122UP and the at least one upper monitoring pad 122MP.

Each of the plurality of upper connection pads 122UP may have a circular shape in a top view but is not limited thereto. For example, each of the plurality of upper connection pads 122UP may have an oval shape, a rectangular shape, or a rectangular shape with rounded corners. The horizontal width of each of the plurality of upper connection pads 122UP, e.g., the diameter of each of the plurality of upper connection pads 122UP when the plurality of upper connection pads 122UP have a circular shape in a top view, may be a first horizontal width W1. For example, the first horizontal width W1 may be about 40 μm to about 80 μm.

The at least one upper monitoring pad 122MP may include a base pad portion BP and at least one protrusion portion PP. In some implementations, the at least one upper monitoring pad 122MP may include a base pad portion BP and four protrusion portions PP.

The base pad portion BP may have a circular shape in a top view but is not limited thereto. For example, the base pad portion BP may have an oval shape, a rectangular shape, or a rectangular shape with rounded corners. An upper connection pad 122UP may have generally the same shape as the base pad portion BP of an upper monitoring pad 122MP in a top view. For example, when the upper connection pad 122UP has a circular shape in a top view, the base pad portion BP of the upper monitoring pad 122MP may also have a circular shape in a top view. The horizontal width of the base pad portion BP of the at least one upper monitoring pad 122MP (e.g., the diameter of the base pad portion BP when the base pad portion BP of the at least one upper monitoring pad 122MP has a circular shape in a top view) may be a second horizontal width W2. In some implementations, the first horizontal width W1 may be substantially the same as the second horizontal width W2. For example, the second horizontal width W2 may be about 40 μm to about 80 μm.

A protrusion portion PP may extend outward from the base pad portion BP in the horizontal direction. For example, the protrusion portion PP may generally have a bar shape in a top view. The protrusion portion PP may have an extension length PL that is less than the second horizontal width W2. For example, the extension length PL of the protrusion portion PP may be about 5 μm to about 25 μm. When the upper monitoring pad 122MP includes four protrusion portions PP extending from the base pad portion BP, the four protrusion portions PP may extend along four extension lines extending in different directions at equal angles therebetween from the center of the base pad portion BP in a top view, respectively. For example, the four protrusion portions PP may extend along four extension lines extending at 90-degree angles therebetween from the center of the base pad portion BP in a top view, respectively.

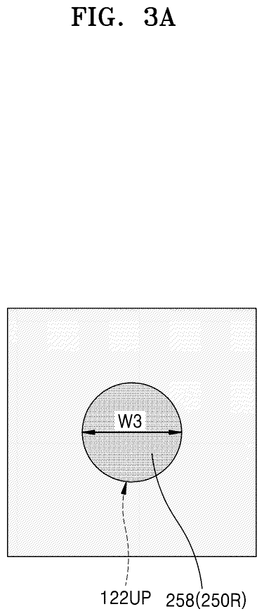

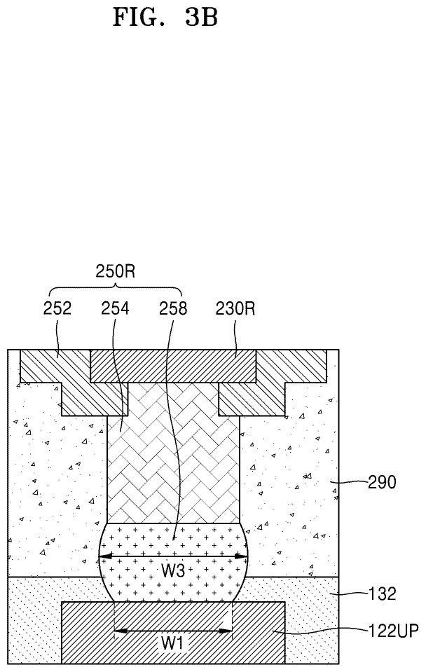

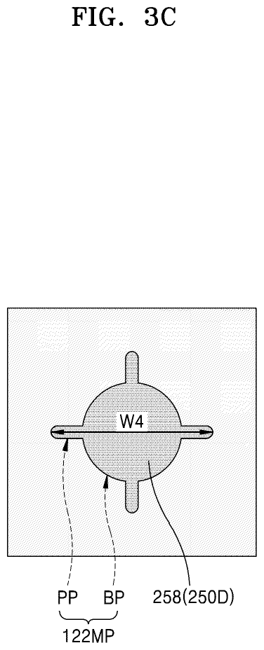

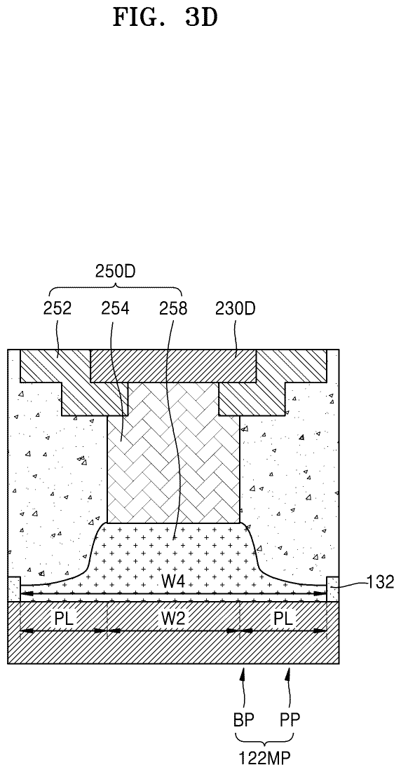

FIGS. 3A to 3D are top views and cross-sectional views illustrating an inspection result of a chip connection terminal connected to an upper connection pad and a chip dummy terminal connected to an upper monitoring pad in a semiconductor package including a printed circuit board. Particularly, FIG. 3A is a top view illustrating an inspection result of a chip connection terminal connected to an upper connection pad, FIG. 3B is a cross-sectional view illustrating the chip connection terminal connected to the upper connection pad, FIG. 3C is a top view illustrating an inspection result of a chip dummy terminal connected to an upper monitoring pad, and FIG. 3D is a cross-sectional view illustrating the chip dummy terminal connected to the upper monitoring pad.

Referring to FIGS. 1 and 3A to 3D, the semiconductor package 1 may include the printed circuit board 100 and the at least one semiconductor chip 200 attached onto the printed circuit board 100.

The printed circuit board 100 may include the at least one substrate base 110, the substrate wiring structure 120, and the solder resist layer 130. The substrate wiring structure 120 may include the plurality of substrate wiring patterns 122 on the upper surface and the lower surface or in the inside of the at least one substrate base 110 and extending in the horizontal direction and may also include the plurality of substrate via patterns 124 extending in the vertical direction by penetrating at least a portion of the at least one substrate base 110, each substrate via pattern 124 electrically connecting two substrate wiring patterns 122 located at different vertical levels among the plurality of substrate wiring patterns 122. The solder resist layer 130 may include the upper solder resist layer 132 covering the upper surface of the at least one substrate base 110 and the lower solder resist layer 134 covering the lower surface of the at least one substrate base 110.

Portions of substrate wiring patterns 122 on the upper surface of the at least one substrate base 110 may be the plurality of upper pads 122P, respectively. For example, portions of substrate wiring patterns 122 at the highest vertical level may be the plurality of upper pads 122P, respectively. The plurality of upper pads 122P may not be covered by the upper solder resist layer 132. The plurality of upper pads 122P may include the plurality of upper connection pads 122UP and the at least one upper monitoring pad 122MP. Each of the plurality of upper connection pads 122UP may have the first horizontal width W1 in a top view. The at least one upper monitoring pad 122MP may include the base pad portion BP and the at least one protrusion portion PP. A protrusion portion PP may extend outward from the base pad portion BP. The upper connection pad 122UP may have generally the same shape as the base pad portion BP of an upper monitoring pad 122MP in a top view. The base pad portion BP may have the second horizontal width W2 in a top view. In some implementations, the first horizontal width W1 may be substantially the same as the second horizontal width W2. The protrusion portion PP may have the extension length PL that is less than the second horizontal width W2.

A semiconductor chip 200 may include the semiconductor substrate 210, the wiring layer 220, and the plurality of chip pads 230. The plurality of chip pads 230 may include the plurality of chip connection pads 230R and the at least one chip dummy pad 230D. The plurality of chip terminals 250 may be attached to the plurality of chip pads 230, respectively. The plurality of chip terminals 250 may include the plurality of chip connection terminals 250R and the at least one chip dummy terminal 250D. The plurality of chip connection terminals 250R may be attached to the plurality of chip connection pads 230R, respectively, and the at least one chip dummy terminal 250D may be attached to the at least one chip dummy pad 230D.

The plurality of chip connection terminals 250R may be attached to the plurality of upper connection pads 122UP, respectively, and the at least one chip dummy terminal 250D may be attached to the at least one upper monitoring pad 122MP. The plurality of chip terminals 250 may be between the plurality of chip pads 230 and the plurality of upper pads 122P, respectively, and electrically connect the at least one semiconductor chip 200 to the printed circuit board 100. The plurality of chip connection terminals 250R may be between the plurality of chip connection pads 230R and the plurality of upper connection pads 122UP, respectively, and the at least one chip dummy terminal 250D may be between the at least one chip dummy pad 230D and the at least one upper monitoring pad 122MP. The plurality of chip connection pads 230R may be electrically connected to the semiconductor device 205 and the wiring layer 220. The at least one chip dummy pad 230D may not be electrically connected to the semiconductor device 205. In some implementations, the at least one chip dummy pad 230D may not be electrically connected to the semiconductor device 205 and the wiring layer 220.

Each of the plurality of chip connection terminals 250R and the at least one chip dummy terminal 250D may include an under bump metal (UBM) layer 252, a conductive pillar 254, and a conductive cap 258. The UBM layer 252 may cover at least a portion of a chip pad 230. The UBM layer 252 may cover a portion of the lower surface, e.g., a portion adjacent to an edge of the lower surface, of the chip pad 230. In some implementations, the UBM layer 252 may cover the side surface of the chip pad 230 and a portion of the lower surface adjacent to the side surface of the chip pad 230. The UBM layer 252 may include Ti, Cu, nickel (Ni), Au, nickel vanadium (NiV), nickel phosphide (NiP), titanium nickel (TiNi), titanium tungsten (TiW), TaN, Al, palladium (Pd), chromium copper (CrCu), or a combination thereof.

The conductive pillar 254 may be attached to the lower surface of the chip pad 230. In some implementations, the UBM layer 252 may be between the chip pad 230 and the conductive pillar 254. For example, the conductive pillar 254 may be attached beneath the chip pad 230 and the UBM layer 252. The conductive pillar 254 may include Cu, Ni, stainless steel, or a Cu alloy, such as beryllium copper. For example, the conductive pillar 254 may be formed by a plating process, such as electrolytic plating or electroless plating. The conductive cap 258 may cover the lower surface of the conductive pillar 254. The conductive cap 258 may include a solder ball or a solder bump. For example, the conductive cap 258 may include Ag, tin (Sn), Au, or solder. In some implementations, the conductive cap 258 may include tin silver (SnAg). The maximum horizontal width of the conductive cap 258 of a chip connection terminal 250R may be a third horizontal width W3. The third horizontal width W3 may be greater than or equal to the first horizontal width W1. The maximum horizontal width of the conductive cap 258 of a chip dummy terminal 250D may be a fourth horizontal width W4. The fourth horizontal width W4 may be greater than the second horizontal width W2. The fourth horizontal width W4 may be greater than the third horizontal width W3. The fourth horizontal width W4 may be the same as the maximum horizontal width of the upper monitoring pad 122MP. In some implementations, the fourth horizontal width W4 may be obtained by adding two extension lengths PL to the second horizontal width W2.

The UBM layer 252, the conductive pillar 254, and the conductive cap 258 of the chip connection terminal 250R may be referred to as a first UBM layer, a first conductive pillar, and a first conductive cap, respectively, and the UBM layer 252, the conductive pillar 254, and the conductive cap 258 of the chip dummy terminal 250D may be referred to as a second UBM layer, a second conductive pillar, and a second conductive cap, respectively.

The at least one semiconductor chip 200 may be disposed on the printed circuit board 100 and then attached to the printed circuit board 100 by a reflow process. For example, the at least one semiconductor chip 200 may be disposed on the printed circuit board 100 such that the plurality of chip terminals 250 are on the plurality of upper pads 122P respectively corresponding thereto, and then a reflow process may be performed for the conductive cap 258 of each of the plurality of chip terminals 250 to be reflowed and attached to a corresponding one of the plurality of upper pads 122P. The reflowed conductive caps 258 may fully cover the upper surfaces of the plurality of upper pads 122P, respectively. For example, the reflowed conductive cap 258 of the chip connection terminal 250R may fully cover the upper surface of the upper connection pad 122UP and the reflowed conductive cap 258 of the chip dummy terminal 250D may fully cover the upper surfaces of the base pad portion BP and the at least one protrusion portion PP included in the upper monitoring pad 122MP. When the upper monitoring pad 122MP includes the base pad portion BP and a plurality of protrusion portions PP, the conductive cap 258 of the chip dummy terminal 250D may fully cover the upper surfaces of the base pad portion BP and the plurality of protrusion portions PP included in the upper monitoring pad 122MP.

After attaching the at least one semiconductor chip 200 onto the printed circuit board 100, X-ray monitoring may be performed on the semiconductor package 1 to inspect the plurality of chip terminals 250 respectively attached to the plurality of upper pads 122P.

Referring to FIGS. 3A and 3B, the conductive cap 258 of the chip connection terminal 250R attached to the upper connection pad 122UP may have a planar shape corresponding to the planar shape of the upper connection pad 122UP. For example, when the planar shape of the chip connection terminal 250R is a circular shape, the planar shape of the conductive cap 258 of the chip connection terminal 250R attached to the upper connection pad 122UP may be a circular shape. The maximum horizontal width of the conductive cap 258 of the chip connection terminal 250R may be the third horizontal width W3. The third horizontal width W3 may be greater than or equal to the first horizontal width W1.

Referring to FIGS. 3C and 3D, the conductive cap 258 of the chip dummy terminal 250D attached to the upper monitoring pad 122MP may have the same planar shape as the planar shape of the upper monitoring pad 122MP. For example, the planar shape of the conductive cap 258 of the chip dummy terminal 250D attached to the upper monitoring pad 122MP may have the same planar shape as the planar shape of the upper monitoring pad 122MP including the at least one protrusion portion PP extending outward from the base pad portion BP. The maximum horizontal width of the conductive cap 258 of the chip dummy terminal 250D may be the fourth horizontal width W4. The fourth horizontal width W4 may be greater than the second horizontal width W2. The fourth horizontal width W4 may be greater than the third horizontal width W3. In some implementations, the fourth horizontal width W4 may be obtained by adding two extension lengths PL to the second horizontal width W2.

Referring to FIGS. 1 and 3A to 3D, X-ray monitoring may be performed on the semiconductor package 1 to observe the planar shape of the conductive caps 258 of the plurality of chip terminals 250 respectively attached to the plurality of upper pads 122P. If the conductive cap 258 of a chip terminal 250 is reflowed and normally wetted on the upper surface of an upper pad 122P by performing a reflow process, the planar shape of the conductive cap 258 may be observed as shown in FIGS. 3A and 3C.

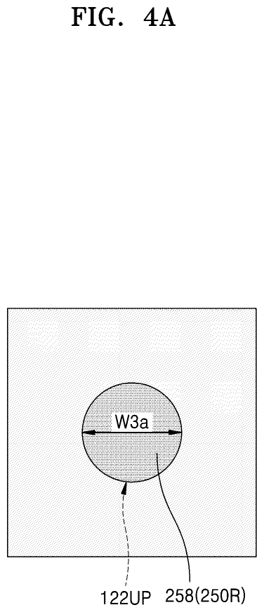

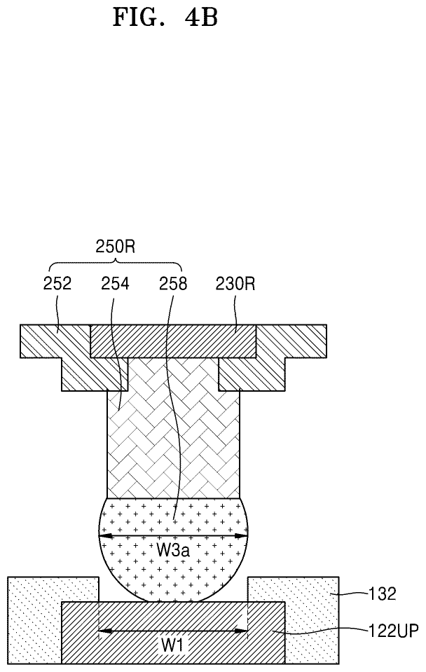

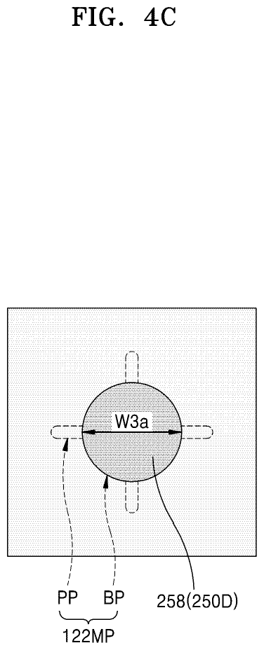

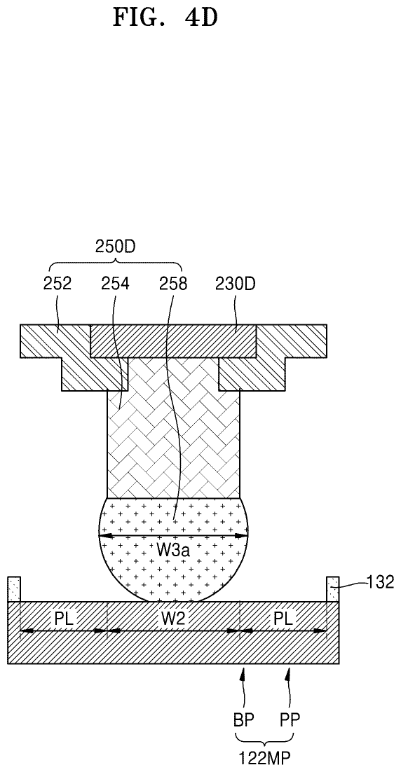

FIGS. 4A to 4D are top views and cross-sectional views illustrating an inspection result of a chip connection terminal on an upper connection pad and a chip dummy terminal on an upper monitoring pad in a semiconductor package including a printed circuit board. Particularly, FIG. 4A is a top view illustrating an inspection result of a chip connection terminal on an upper connection pad, FIG. 4B is a cross-sectional view illustrating the chip connection terminal on the upper connection pad, FIG. 4C is a top view illustrating an inspection result of a chip dummy terminal on an upper monitoring pad, and FIG. 4D is a cross-sectional view illustrating the chip dummy terminal on the upper monitoring pad.

Referring to FIGS. 1 and 4A to 4D, the semiconductor package 1 may include the printed circuit board 100 and the at least one semiconductor chip 200 attached onto the printed circuit board 100.

The plurality of chip connection terminals 250R may be between the plurality of chip connection pads 230R and the plurality of upper connection pads 122UP, respectively, and the at least one chip dummy terminal 250D may be between the at least one chip dummy pad 230D and the at least one upper monitoring pad 122MP.

The maximum horizontal width of the conductive cap 258 of a chip connection terminal 250R may be a third horizontal width W3a. The third horizontal width W3a may be greater than or equal to the first horizontal width W1.

Referring to FIGS. 4A and 4B, if the conductive cap 258 of a chip connection terminal 250R on an upper connection pad 122UP is reflowed but abnormally wetted to thereby result in non-wet failure, the planar shape of the conductive cap 258 of the chip connection terminal 250R may be a circular shape. For example, the abnormally reflowed conductive cap 258 of the chip connection terminal 250R may not cover at least a portion of the upper surface of the upper connection pad 122UP. The maximum horizontal width of the conductive cap 258 of the chip connection terminal 250R may be the third horizontal width W3a. The third horizontal width W3a may be greater than or equal to the first horizontal width W1. The third horizontal width W3a may be the same as or similar to the third horizontal width W3 shown in FIGS. 3A and 3B.

Referring to FIGS. 4C and 4D, if the conductive cap 258 of a chip dummy terminal 250D on an upper monitoring pad 122MP is reflowed but abnormally wetted, the planar shape of the conductive cap 258 of the chip dummy terminal 250D may be a circular shape. The abnormally reflowed conductive cap 258 of the chip dummy terminal 250D may not cover at least a portion of the upper surface of the upper monitoring pad 122MP. For example, the abnormally reflowed conductive cap 258 of the chip dummy terminal 250D may not cover the upper surface of the base pad portion BP of the upper monitoring pad 122MP or cover only a portion of the upper surface but not cover the other portion of the upper surface. For example, the abnormally reflowed conductive cap 258 of the chip dummy terminal 250D may not cover the upper surface of the protrusion portion PP of the upper monitoring pad 122MP. The maximum horizontal width of the conductive cap 258 of the chip dummy terminal 250D may be the third horizontal width W3a that is equal to the maximum horizontal width of the conductive cap 258 of the chip connection terminal 250R.

Referring to FIGS. 1 and 4A to 4D, X-ray monitoring may be performed on the semiconductor package 1 to observe the planar shape of the conductive caps 258 of the plurality of chip terminals 250 respectively attached to the plurality of upper pads 122P. If the conductive cap 258 of a chip terminal 250 is reflowed but abnormally wetted on the upper surface of an upper pad 122P by performing a reflow process, it may be observed as shown in FIGS. 4A and 4C that the planar shape of the conductive cap 258 of the chip connection terminal 250R is substantially the same as the planar shape of the conductive cap 258 of the chip dummy terminal 250D.

Referring to FIGS. 1 to 4D, if the conductive cap 258 of a chip terminal 250 is reflowed and normally wetted on the upper surface of an upper pad 122P, it may be observed as shown in FIGS. 3A and 3C that the planar shape of the conductive cap 258 of the chip connection terminal 250R is different from the planar shape of the conductive cap 258 of the chip dummy terminal 250D. However, if bending or the like occurs on the printed circuit board 100 and/or the at least one semiconductor chip 200 included in the semiconductor package 1 such that the conductive cap 258 of a chip terminal 250 is reflowed but abnormally wetted on the upper surface of an upper pad 122P to thereby result in non-wet failure, it may be observed as shown in FIGS. 4A and 4C that the planar shape of the conductive cap 258 of the chip connection terminal 250R is substantially the same as the planar shape of the conductive cap 258 of the chip dummy terminal 250D.

Because the plurality of upper pads 122P include the at least one upper monitoring pad 122MP in the printed circuit board 100 and the semiconductor package 1 including the same, after attaching the at least one semiconductor chip 200 onto the printed circuit board 100, X-ray monitoring may be performed on the semiconductor package 1 to observe the planar shape of the conductive cap 258 of the chip dummy terminal 250D on the at least one upper monitoring pad 122MP, thereby inspecting whether the plurality of chip terminals 250 are normally attached to the plurality of upper pads 122P, respectively. Therefore, the electrical connection reliability between the printed circuit board 100 and the at least one semiconductor chip 200 may be easily inspected to provide that the reliability of the printed circuit board 100 electrical connection may be ensured and also that of the semiconductor package 1 including the printed circuit board 100.

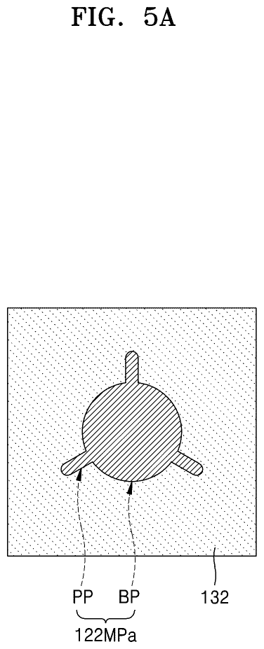

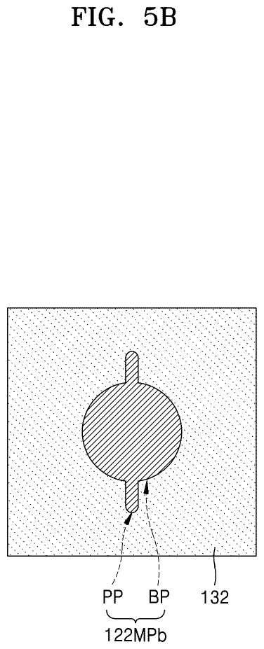

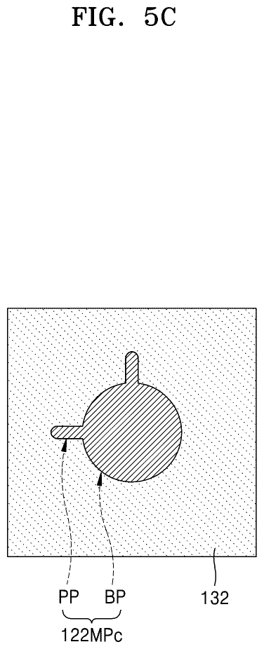

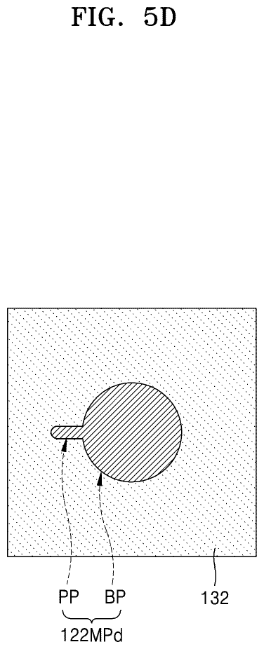

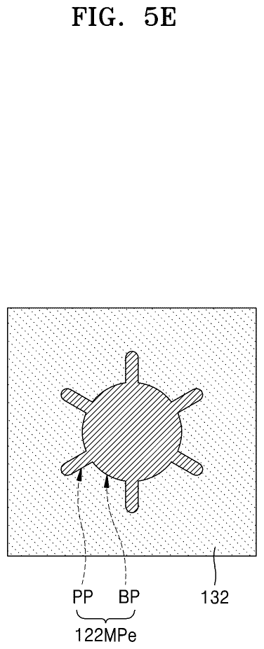

FIGS. 5A to 5E are top views illustrating upper monitoring pads 122MPa, 122MPb, 122MPc, 122MPd, and 122MPe of a printed circuit board.

Referring to FIG. 5A, the upper monitoring pad 122MPa may include the base pad portion BP and three protrusion portions PP. The three protrusion portions PP may extend along three extension lines extending in different directions at equal angles therebetween from the center of the base pad portion BP in a top view, respectively. For example, the three protrusion portions PP may extend along three extension lines extending at 120-degree angles therebetween from the center of the base pad portion BP in a top view, respectively.

Referring to FIG. 5B, the upper monitoring pad 122MPb may include the base pad portion BP and two protrusion portions PP. The two protrusion portions PP may extend along two extension lines extending in different directions at equal angles therebetween from the center of the base pad portion BP in a top view, respectively. For example, the two protrusion portions PP may extend along two extension lines extending at 180-degree angles therebetween from the center of the base pad portion BP in a top view, respectively. That is, the two protrusion portions PP may extend in opposite directions from the base pad portion BP along an extension line extending by passing through the center of the base pad portion BP in a top view.

Referring to FIG. 5C, the upper monitoring pad 122MPc may include the base pad portion BP and two protrusion portions PP. The two protrusion portions PP may extend along two extension lines extending in different directions from the center of the base pad portion BP in a top view, respectively. In some implementations, the two protrusion portions PP may respectively extend along two extension lines extending at a 90-degree angle therebetween from the center of the base pad portion BP in a top view but are not limited thereto. For example, the two protrusion portions PP may respectively extend along two extension lines extending at an angle, such as 30 degrees, 45 degrees, 60 degrees, or 120 degrees, greater than 0 degrees and less than 180 degrees from the center of the base pad portion BP in a top view.

Referring to FIG. 5D, the upper monitoring pad 122MPd may include the base pad portion BP and one protrusion portion PP. The one protrusion portion PP may extend along one extension line extending from the center of the base pad portion BP in a top view.

Referring to FIG. 5E, the upper monitoring pad 122MPe may include the base pad portion BP and six protrusion portions PP. The six protrusion portions PP may extend along six extension lines extending in different directions at equal angles therebetween from the center of the base pad portion BP in a top view, respectively. For example, the six protrusion portions PP may extend along six extension lines extending at 60-degree angles therebetween from the center of the base pad portion BP in a top view, respectively.

Referring to FIGS. 2B and 5A to 5E, although it is shown that each of the upper monitoring pads 122MP, 122MPa, 122MPb, 122MPc, 122MPd, and 122MPe includes the base pad portion BP and one, two, three, four, or six protrusion portions PP extending from the base pad portion BP, this is only illustrative and is not limited thereto, and each of the upper monitoring pads 122MP, 122MPa, 122MPb, 122MPc, 122MPd, and 122MPe may include five or seven or more protrusion portions PP extending from the base pad portion BP.

In addition, although FIGS. 2B, 5A, 5B, 5C, and 5E show that the respective extension lengths of protrusion portions PP extending from the base pad portion BP are the same as each other, this is only illustrative and is not limited thereto, and at least one of the protrusion portions PP extending from the base pad portion BP may have a length different from the length of at least one other protrusion portion PP.

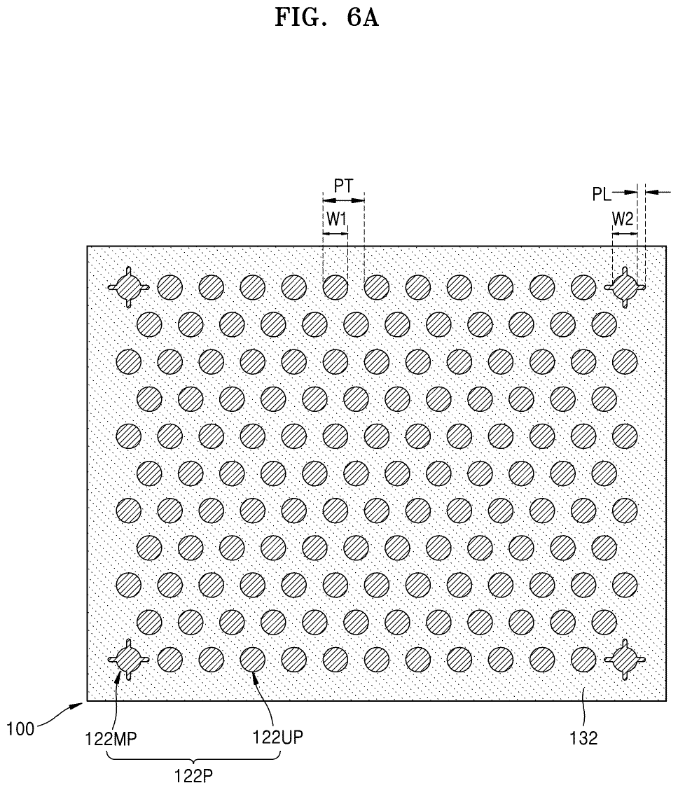

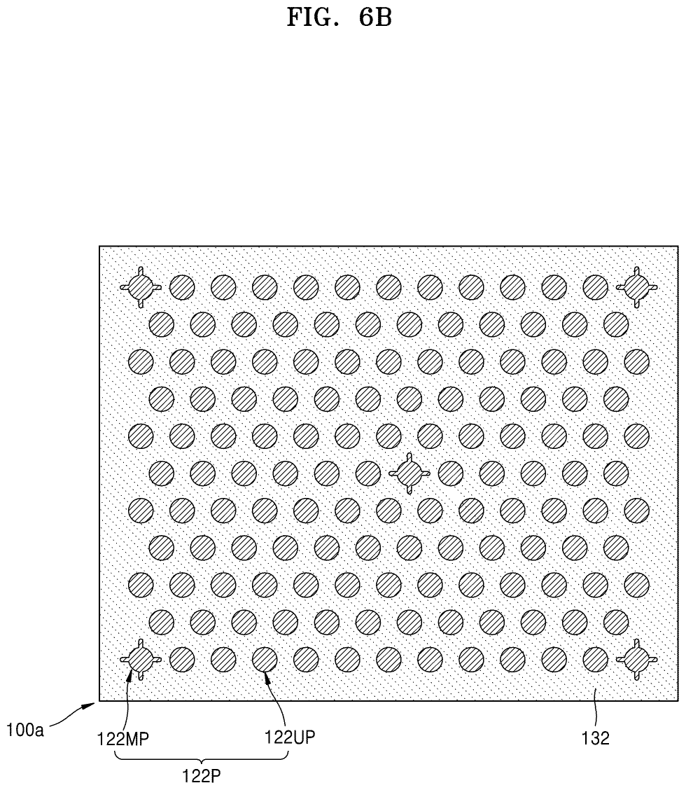

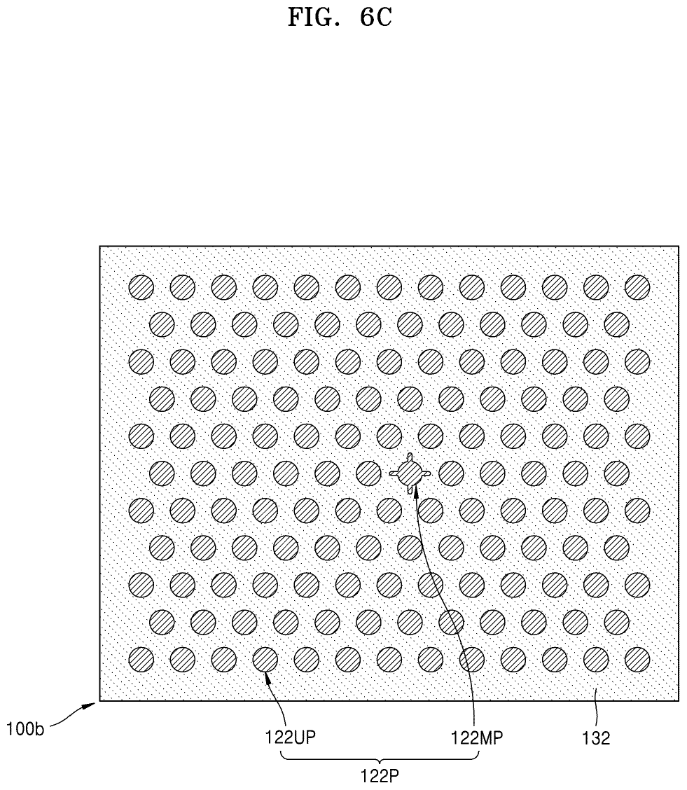

FIGS. 6A to 6C are top views illustrating printed circuit boards 100, 100a, and 100b. A description made with reference to FIGS. 6A to 6C may refer to FIG. 1 together.

Referring to FIG. 6A, the printed circuit board 100 may include the plurality of upper pads 122P. In some implementations, in a top view, the plurality of upper pads 122P may be arranged in a honeycomb formation in that the plurality of upper pads 122P are arranged zigzag in a first horizontal direction or a second horizontal direction, the first horizontal direction being perpendicular to the second horizontal direction, but the plurality of upper pads 122P are not limited thereto. For example, in a top view, the plurality of upper pads 122P may be arranged in a matrix form in which the plurality of upper pads 122P are arranged on a line along each of the first horizontal direction and the second horizontal direction. In a top view, the plurality of upper pads 122P may be arranged with a pad pitch PT between the plurality of upper pads 122P. The pad pitch PT may be about 80 μm to about 120 μm.

The plurality of upper pads 122P may not be covered by the upper solder resist layer 132. The plurality of upper pads 122P may include the plurality of upper connection pads 122UP and the at least one upper monitoring pad 122MP.

An upper monitoring pad 122MP may correspond to a chip dummy pad 230D that is not connected (NC) and a chip dummy terminal 250D attached to the chip dummy pad 230D among the plurality of chip pads 230 included in the at least one semiconductor chip 200 and the plurality of chip terminals 250 respectively attached to the plurality of chip pads 230. Although FIG. 1 shows that the upper monitoring pad 122MP is connected to each chip dummy terminal 250D attached to every chip dummy pad 230D, this is illustrative and is not limited thereto. For example, the number of upper monitoring pads 122MP in the plurality of upper pads 122P may be less than or equal to the number of chip dummy terminals 250D attached to corresponding chip dummy pads 230D among the plurality of chip terminals 250 respectively attached to the plurality of chip pads 230.

Each of the plurality of upper connection pads 122UP may have the first horizontal width W1. The at least one upper monitoring pad 122MP may include the base pad portion BP and the at least one protrusion portion PP extending outward from the base pad portion BP. In some implementations, the at least one upper monitoring pad 122MP may include the base pad portion BP and four protrusion portions PP extending outward from the base pad portion BP. The base pad portion BP may have the second horizontal width W2. In some implementations, the first horizontal width W1 may be substantially the same as the second horizontal width W2. A protrusion portion PP may have the extension length PL that is less than the second horizontal width W2. The extension length PL of the protrusion portion PP may be less than the difference between the pad pitch PT and the first horizontal width W1.

In some implementations, each upper monitoring pad 122MP in the plurality of upper pads 122P may be arranged adjacent to a corner of the printed circuit board 100 in a top view. For example, when the plurality of upper pads 122P include four upper monitoring pads 122MP, the four upper monitoring pads 122MP may be arranged adjacent to the four corners of the printed circuit board 100 in a top view, respectively. Although FIG. 6A shows that only one upper monitoring pad 122MP is arranged adjacent to each of the four corners of the printed circuit board 100 in a top view, the present embodiment is not limited thereto. For example, one or more upper monitoring pads 122MP may be arranged adjacent to each of the four corners of the printed circuit board 100 in a top view.

Although FIG. 6A shows that an upper monitoring pad 122MP is most adjacent to each of the four corners of the printed circuit board 100 among the plurality of upper pads 122P in a top view, the present embodiment is not limited thereto. For example, an upper monitoring pad 122MP is adjacent to a corner of the printed circuit board 100, but at least one of the plurality of upper connection pads 122UP may be arranged to be closer to the corner of the printed circuit board 100 than the upper monitoring pad 122MP. An upper monitoring pad 122MP may be arranged to correspond to a chip dummy terminal 250D attached to a chip dummy pad 230D adjacent to a corner of the at least one semiconductor chip 200 in a top view. The chip dummy pads 230D are NC among the plurality of chip terminals 250 attached to the plurality of chip pads 230.

For example, when the at least one semiconductor chip 200 attached to the printed circuit board 100 has smiley face bending, there is a high possibility that a non-wet failure has occurred between a chip terminal 250 adjacent to a corner of the at least one semiconductor chip 200 and an upper pad 122P in a top view. However, because the printed circuit board 100 includes an upper monitoring pad 122MP adjacent to a corner of the printed circuit board 100 in a top view, it may be easily inspected whether the plurality of chip terminals 250 are normally attached to the plurality of upper pads 122P, respectively. Therefore, the electrical connection reliability between the printed circuit board 100 and the at least one semiconductor chip 200 may be easily inspected to provide that the reliability of the printed circuit board 100 electrical connection may be ensured and also that of the semiconductor package 1 including the printed circuit board 100.

Referring to FIG. 6B, the printed circuit board 100a may include the plurality of upper pads 122P. The plurality of upper pads 122P may include the plurality of upper connection pads 122UP and the at least one upper monitoring pad 122MP. In some implementations, each upper monitoring pad 122MP in the plurality of upper pads 122P may be arranged adjacent to a corner or the center of the printed circuit board 100 in a top view. For example, when the plurality of upper pads 122P include five upper monitoring pads 122MP, four of the five upper monitoring pads 122MP may be arranged adjacent to the four corners of the printed circuit board 100 in a top view, respectively, and the remaining one upper monitoring pad 122MP may be arranged adjacent to the center of the printed circuit board 100 in a top view. Although FIG. 6B shows that only one upper monitoring pad 122MP is arranged adjacent to each of the four corners and the center of the printed circuit board 100 in a top view, the present embodiment is not limited thereto. For example, one or more upper monitoring pads 122MP may be arranged adjacent to each of the four corners and adjacent to the center of the printed circuit board 100 in a top view.

For example, when the at least one semiconductor chip 200 attached to the printed circuit board 100 has twist bending, there is a high possibility that non-wet failure between a chip terminal 250 and an upper pad 122P occurs at several positions in a top view. However, because the printed circuit board 100a includes upper monitoring pads 122MP adjacent to the corners and the center of the printed circuit board 100a in a top view, it may be easily inspected whether the plurality of chip terminals 250 are normally attached to the plurality of upper pads 122P, respectively.

Referring to FIG. 6C, the printed circuit board 100b may include the plurality of upper pads 122P. The plurality of upper pads 122P may include the plurality of upper connection pads 122UP and the at least one upper monitoring pad 122MP. In some implementations, the at least one upper monitoring pad 122MP in the plurality of upper pads 122P may be arranged adjacent to the center of the printed circuit board 100b in a top view. For example, when the plurality of upper pads 122P include one upper monitoring pad 122MP, the upper monitoring pad 122MP may be arranged adjacent to the center of the printed circuit board 100b in a top view. Although FIG. 6C shows that only one upper monitoring pad 122MP is arranged adjacent to the center of the printed circuit board 100b in a top view, the present embodiment is not limited thereto. For example, one or more upper monitoring pads 122MP may be arranged adjacent to the center of the printed circuit board 100b in a top view.

For example, when the at least one semiconductor chip 200 attached to the printed circuit board 100b has crying face bending, there is a high possibility that non-wet failure occurs between a chip terminal 250 adjacent to the center of the at least one semiconductor chip 200 and an upper pad 122P in a top view. However, because the printed circuit board 100b includes an upper monitoring pad 122MP adjacent to the center of the printed circuit board 100b in a top view, it may be easily inspected whether the plurality of chip terminals 250 are normally attached to the plurality of upper pads 122P, respectively.

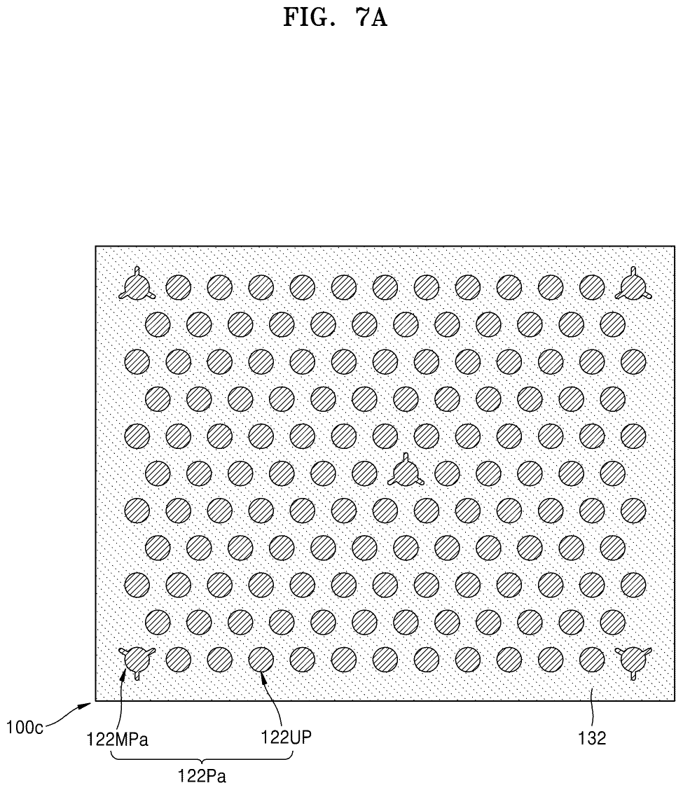

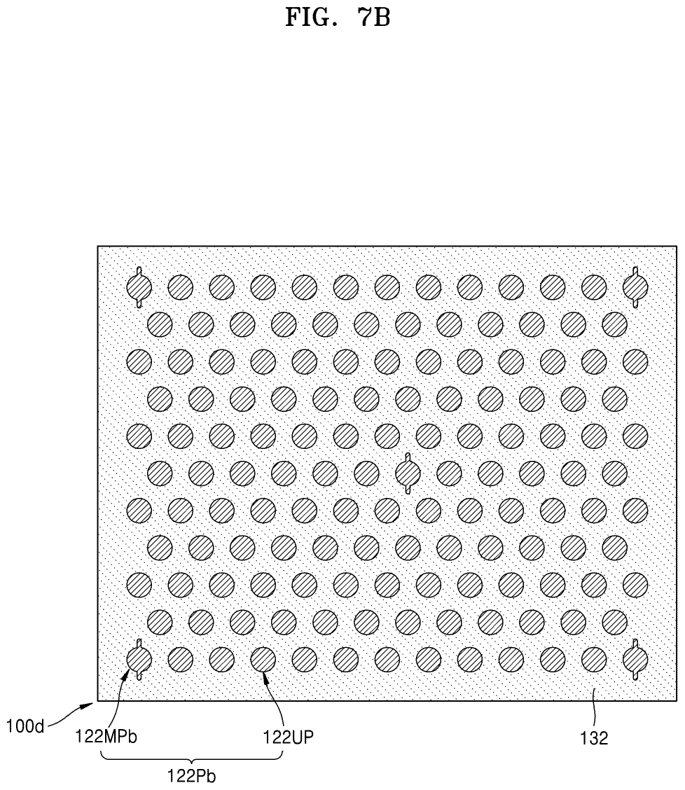

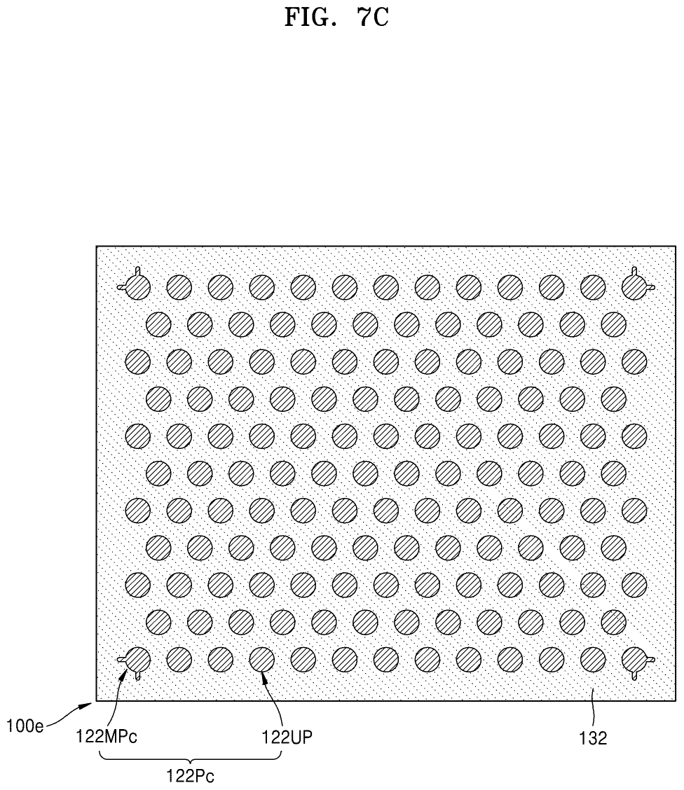

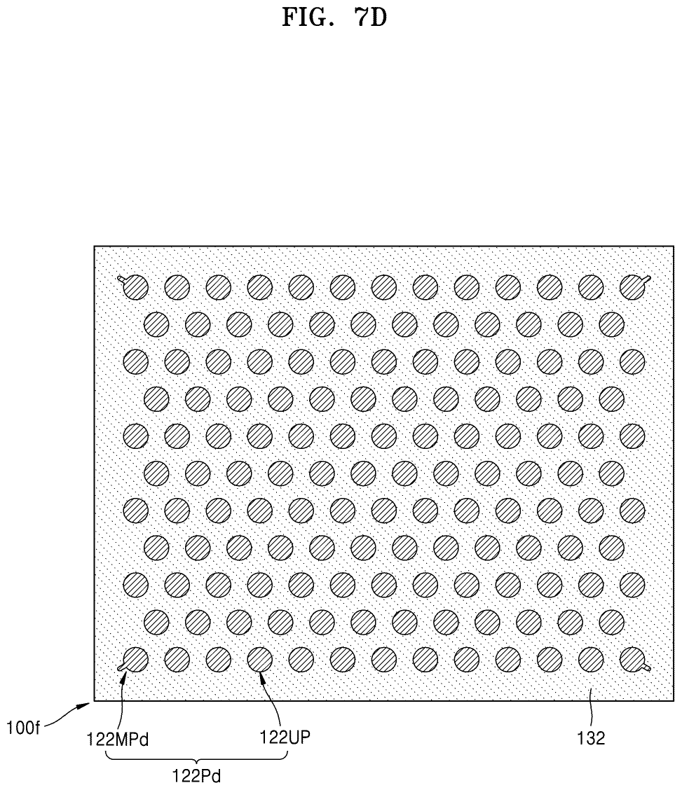

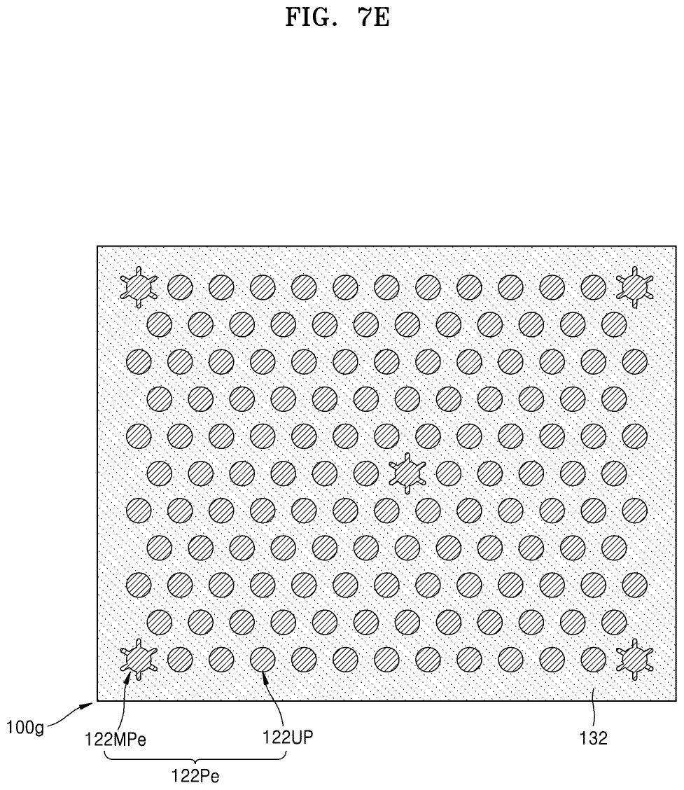

FIGS. 7A to 7E are top views illustrating printed circuit boards 100c, 100d, 100e, 100f, and 100g. A description made with reference to FIGS. 7A to 7E may refer to FIG. 1 together.

Referring to FIG. 7A, the printed circuit board 100c may include a plurality of upper pads 122Pa. The plurality of upper pads 122Pa may include the plurality of upper connection pads 122UP and a plurality of upper monitoring pad 122MPa. An upper monitoring pad 122MPa may be the same as the upper monitoring pad 122MPa shown in FIG. 5A. In some implementations, each upper monitoring pad 122MPa in the plurality of upper pads 122Pa may be arranged adjacent to a corner or the center of the printed circuit board 100c in a top view. In some implementations, the planar shape of at least one of the plurality of upper monitoring pads 122MPa may be obtained by rotating, by 180 degrees, the planar shape of at least one other of the plurality of upper monitoring pads 122MPa. For example, when the plurality of upper pads 122Pa include five upper monitoring pads 122MPa, four of the five upper monitoring pads 122MPa may be arranged adjacent to the four corners of the printed circuit board 100c in a top view, respectively, and the remaining one upper monitoring pad 122MPa may be arranged adjacent to the center of the printed circuit board 100c in a top view, but the present embodiment is not limited thereto. For example, similar to the plurality of upper pads 122P included in the printed circuit board 100 shown in FIG. 6A, the plurality of upper pads 122Pa may include four upper monitoring pads 122MPa respectively arranged adjacent to the four corners of the printed circuit board 100c in a top view, or similar to the plurality of upper pads 122P included in the printed circuit board 100b shown in FIG. 6C, the plurality of upper pads 122Pa may include one upper monitoring pad 122MPa arranged adjacent to the center of the printed circuit board 100c in a top view.

Referring to FIG. 7B, the printed circuit board 100d may include a plurality of upper pads 122Pb. The plurality of upper pads 122Pb may include the plurality of upper connection pads 122UP and at least one upper monitoring pad 122MPb. An upper monitoring pad 122MPb may be the same as the upper monitoring pad 122MPb shown in FIG. 5B. In some implementations, each upper monitoring pad 122MPb in the plurality of upper pads 122Pb may be arranged adjacent to a corner or the center of the printed circuit board 100d in a top view. For example, when the plurality of upper pads 122Pb include five upper monitoring pads 122MPb, four of the five upper monitoring pads 122MPb may be arranged adjacent to the four corners of the printed circuit board 100d in a top view, respectively, and the remaining one upper monitoring pad 122MPb may be arranged adjacent to the center of the printed circuit board 100d in a top view, but the present embodiment is not limited thereto. For example, similar to the plurality of upper pads 122P included in the printed circuit board 100 shown in FIG. 6A, the plurality of upper pads 122Pb may include four upper monitoring pads 122MPb respectively arranged adjacent to the four corners of the printed circuit board 100d in a top view, or similar to the plurality of upper pads 122P included in the printed circuit board 100b shown in FIG. 6C, the plurality of upper pads 122Pb may include one upper monitoring pad 122MPb arranged adjacent to the center of the printed circuit board 100d in a top view.

Referring to FIG. 7C, the printed circuit board 100e may include a plurality of upper pads 122Pc. The plurality of upper pads 122Pc may include the plurality of upper connection pads 122UP and a plurality of upper monitoring pads 122MPc. An upper monitoring pad 122MPc may be the same as the upper monitoring pad 122MPc shown in FIG. 5C. In some implementations, each upper monitoring pad 122MPc in the plurality of upper pads 122Pc may be arranged adjacent to a corner of the printed circuit board 100e in a top view. In some implementations, the planar shape of at least one of the plurality of upper monitoring pads 122MPc may be obtained by rotating, by 90 degrees, the planar shape of at least one other of the plurality of upper monitoring pads 122MPc. For example, when the plurality of upper pads 122Pc include four upper monitoring pads 122MPc, the four upper monitoring pads 122MPc may be arranged adjacent to the four corners of the printed circuit board 100e in a top view, respectively, but the present embodiment is not limited thereto. For example, similar to the plurality of upper pads 122P included in the printed circuit board 100a shown in FIG. 6B, the plurality of upper pads 122Pc may include five upper monitoring pads 122MPc respectively arranged adjacent to the four corners and the center of the printed circuit board 100e in a top view, or similar to the plurality of upper pads 122P included in the printed circuit board 100c shown in FIG. 6C, the plurality of upper pads 122Pc may include one upper monitoring pad 122MPc arranged adjacent to the center of the printed circuit board 100e in a top view.

Referring to FIG. 7D, the printed circuit board 100f may include a plurality of upper pads 122Pd. The plurality of upper pads 122Pd may include the plurality of upper connection pads 122UP and a plurality of upper monitoring pads 122MPd. An upper monitoring pad 122MPd may be the same as the upper monitoring pad 122MPd shown in FIG. 5D. In some implementations, the plurality of upper monitoring pads 122MPd in the plurality of upper pads 122Pd may be arranged adjacent to the corners of the printed circuit board 100f in a top view, respectively. In some implementations, the planar shape of at least one of the plurality of upper monitoring pads 122MPd may be obtained by rotating, by 90 degrees, the planar shape of at least one other of the plurality of upper monitoring pads 122MPd. For example, when the plurality of upper pads 122Pd include four upper monitoring pads 122MPd, the four upper monitoring pads 122MPd may be arranged adjacent to the four corners of the printed circuit board 100f in a top view, respectively, but the present embodiment is not limited thereto. For example, similar to the plurality of upper pads 122P included in the printed circuit board 100a shown in FIG. 6B, the plurality of upper pads 122Pd may include five upper monitoring pads 122MPd respectively arranged adjacent to the four corners and the center of the printed circuit board 100f in a top view, or similar to the plurality of upper pads 122P included in the printed circuit board 100c shown in FIG. 6C, the plurality of upper pads 122Pd may include one upper monitoring pad 122MPd arranged adjacent to the center of the printed circuit board 100f in a top view.

Referring to FIG. 7E, the printed circuit board 100g may include a plurality of upper pads 122Pe. The plurality of upper pads 122Pe may include the plurality of upper connection pads 122UP and at least one upper monitoring pad 122MPe. An upper monitoring pad 122MPe may be the same as the upper monitoring pad 122MPe shown in FIG. 5E. In some implementations, each upper monitoring pad 122MPe in the plurality of upper pads 122Pe may be arranged adjacent to a corner or the center of the printed circuit board 100g in a top view. For example, when the plurality of upper pads 122Pe include five upper monitoring pads 122MPe, four of the five upper monitoring pads 122MPe may be arranged adjacent to the four corners of the printed circuit board 100g in a top view, respectively, and the remaining one upper monitoring pad 122MPe may be arranged adjacent to the center of the printed circuit board 100g in a top view, but the present embodiment is not limited thereto. For example, similar to the plurality of upper pads 122P included in the printed circuit board 100 shown in FIG. 6A, the plurality of upper pads 122Pe may include four upper monitoring pads 122MPe respectively arranged adjacent to the four corners of the printed circuit board 100g in a top view, or similar to the plurality of upper pads 122P included in the printed circuit board 100b shown in FIG. 6C, the plurality of upper pads 122Pe may include one upper monitoring pad 122MPe arranged adjacent to the center of the printed circuit board 100g in a top view.

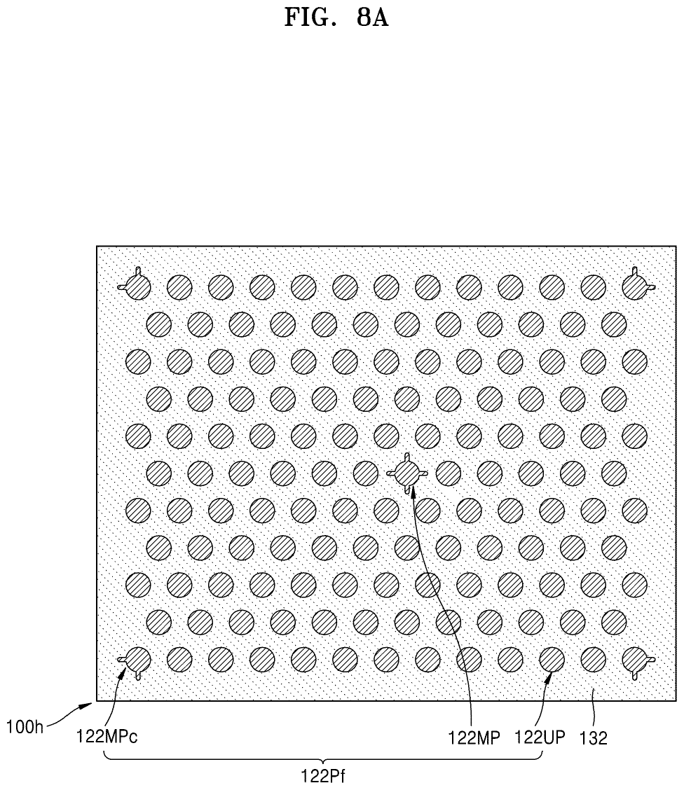

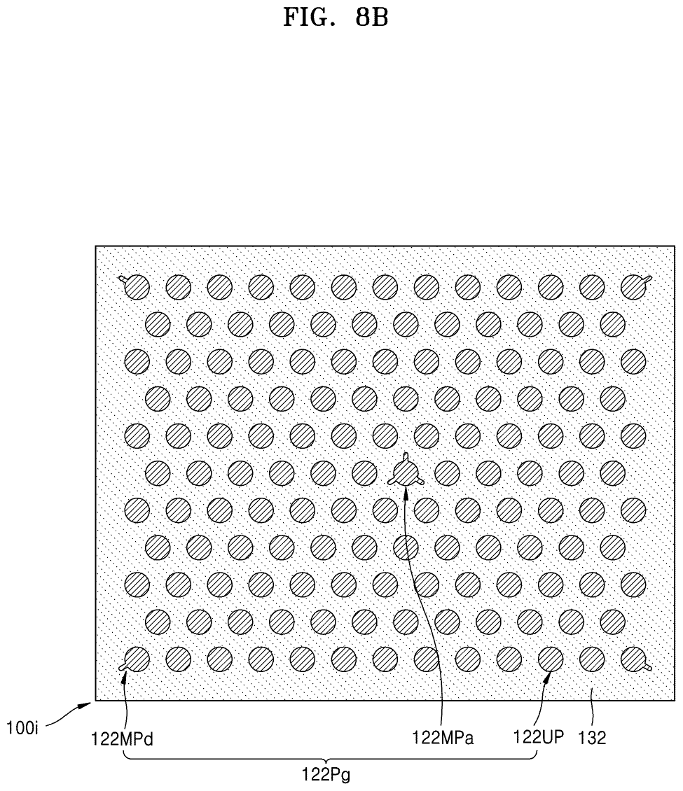

FIGS. 8A and 8B are top views illustrating printed circuit boards 100h and 100i. A description made with reference to FIGS. 8A and 8B may refer to FIG. 1 together.

Referring to FIG. 8A, the printed circuit board 100h may include a plurality of upper pads 122Pf. The plurality of upper pads 122Pf may include the plurality of upper connection pads 122UP, at least one first upper connection pad 122MP, and second upper monitoring pads 122MPc. A first upper connection pad 122MP may be the upper monitoring pad 122MP shown in FIG. 2B, and a second upper monitoring pad 122MPc may be the upper monitoring pad 122MPc shown in FIG. 5C. In some implementations, the at least one first upper connection pad 122MP in the plurality of upper pads 122Pf may be arranged adjacent to the center of the printed circuit board 100h in a top view and the second upper monitoring pads 122MPc may be arranged adjacent to the corners of the printed circuit board 100h in a top view. For example, when the plurality of upper pads 122Pf include one first upper monitoring pad 122MP and four second upper monitoring pads 122MPc, the one first upper monitoring pad 122MP may be arranged adjacent to the center of the printed circuit board 100h in a top view and the four second upper monitoring pads 122MPc may be respectively arranged adjacent to the four corners of the printed circuit board 100h in a top view.

Referring to FIG. 8B, the printed circuit board 100i may include a plurality of upper pads 122Pg. The plurality of upper pads 122Pg may include the plurality of upper connection pads 122UP, at least one first upper connection pad 122MPa, and second upper monitoring pads 122MPd. A first upper connection pad 122MPa may be the upper monitoring pad 122MPa shown in FIG. 5A, and a second upper monitoring pad 122MPd may be the upper monitoring pad 122MPd shown in FIG. 5D. In some implementations, the at least one first upper connection pad 122MPa in the plurality of upper pads 122Pg may be arranged adjacent to the center of the printed circuit board 100i in a top view and the second upper monitoring pads 122MPd may be arranged adjacent to the corners of the printed circuit board 100i in a top view. For example, when the plurality of upper pads 122Pg include one first upper monitoring pad 122MPa and four second upper monitoring pads 122MPd, the one first upper monitoring pad 122MPa may be arranged adjacent to the center of the printed circuit board 100i in a top view and the four second upper monitoring pads 122MPd may be respectively arranged adjacent to the four corners of the printed circuit board 100i in a top view.

Referring to FIGS. 8A and 8B, each of the printed circuit boards 100h and 100i may include two types of upper monitoring pads having different planar shapes. For example, the protrusion portions PP (see FIGS. 2B and 5A) included in the first upper monitoring pads 122MP and 122MPa at the centers of the printed circuit boards 100h and 100i may extend along extension lines extending in different directions at equal angles therebetween from the centers of the base pad portions BP (see FIGS. 2B and 5A), respectively. Although it is shown that the at least one first upper connection pad 122MP shown in FIG. 8A includes four protrusion portions PP and the at least one first upper connection pad 122MPa shown in FIG. 8B includes three protrusion portions PP, the present embodiment is not limited thereto, and the at least one first upper connection pad 122MP or 122MPa may include five or more protrusion portions PP. The planar shape of at least one of the second upper monitoring pads 122MPc and 122MPd at the corners of the printed circuit boards 100h and 100i may be obtained by rotating, by 90 degrees, the planar shape of at least one other thereof. For example, each of the protrusion portions PP (see FIGS. 5C and 5D) included in the second upper monitoring pads 122MPc and 122MPd at the corners of the printed circuit boards 100h and 100i may be arranged to extend toward the outsides of the printed circuit boards 100h and 100i.

In addition, although FIG. 8A shows that the printed circuit board 100h includes the upper monitoring pad 122MPb shown in FIG. 2B and the upper monitoring pad 122MPc shown in FIG. 5C and FIG. 8B shows that the printed circuit board 100i includes the upper monitoring pad 122MPa shown in FIG. 5A and the upper monitoring pad 122MPd shown in FIG. 5D, this is illustrative and is not limited thereto. For example, it is also possible to form a printed circuit board having at least two types of upper monitoring pads among the upper monitoring pads 122MP, 122MPa, 122MPb, 122MPc, 122MPd, and 122MPe shown in FIGS. B and 5A to 5E and modifications thereof.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the printed circuit board has been particularly shown and described with reference to embodiments thereof, it will be understood that various changes in form and details may be made therein without departing from the spirit and scope of the following claims.

What is claimed is:

1. A printed circuit board comprising:
a substrate base;
a plurality of upper pads on an upper surface of the substrate base and comprising a plurality of upper connection pads and at least one upper monitoring pad;
a plurality of lower connection pads beneath a lower surface of the substrate base; and
a substrate wiring structure electrically connecting the plurality of upper connection pads to the plurality of lower connection pads,
wherein the at least one upper monitoring pad comprises a base pad portion having the same planar shape as each of the plurality of upper connection pads and a protrusion portion extending in a horizontal direction from the base pad portion.

2. The printed circuit board of claim 1, further comprising an upper solder resist layer covering the upper surface of the substrate base,
wherein a first portion of each of the plurality of upper pads is covered by the upper solder resist layer, and wherein a second portion of each of the plurality of upper pads is not covered by the upper solder resist layer.

3. The printed circuit board of claim 1, wherein each of the plurality of upper connection pads has a first horizontal width, the base pad portion has a second horizontal width, and the protrusion portion has an extension length that is less than the second horizontal width.

4. The printed circuit board of claim 3, wherein the first horizontal width is the same as the second horizontal width.

5. The printed circuit board of claim 1, wherein the at least one upper monitoring pad comprises a plurality of protrusion portions.

6. The printed circuit board of claim 5, wherein each protrusion portion of the plurality of protrusion portions extends along extension lines extending in different directions at equal angles therebetween from a center of the base pad portion.

7. The printed circuit board of claim 1, wherein the protrusion portion comprises two protrusion portions included in the at least one upper monitoring pad, and the two protrusion portions extend along two extension lines extending in different directions, respectively, at an angle greater than 0 degrees and less than 180 degrees therebetween from a center of the base pad portion in a top view.

8. The printed circuit board of claim 1, wherein the at least one upper monitoring pad is arranged adjacent to a corner of the printed circuit board in a top view.

9. The printed circuit board of claim 1, wherein the at least one upper monitoring pad comprises a plurality of upper monitoring pads greater than or equal to 4, and the plurality of upper monitoring pads are arranged adjacent to four corners of the printed circuit board in a top view.

10. The printed circuit board of claim 1, wherein the at least one upper monitoring pad is arranged adjacent to a center of the printed circuit board in a top view.

11. A semiconductor package comprising:
a printed circuit board comprising
a substrate base,
an upper solder resist layer covering an upper surface of the substrate base,
a plurality of upper pads on the upper surface of the substrate base, the plurality of upper pads comprising a plurality of upper connection pads and at least one upper monitoring pad, and wherein a first portion of each of the plurality of upper pads is covered by the upper solder resist layer and wherein a second portion of each of the plurality of upper pads is not covered by the upper solder resist layer,
a plurality of lower connection pads beneath a lower surface of the substrate base, and
a substrate wiring structure electrically connecting the plurality of upper connection pads to the plurality of lower connection pads, respectively;
a semiconductor chip comprising
a semiconductor substrate and
a plurality of chip pads beneath a lower surface of the semiconductor substrate and comprising a plurality of chip connection pads and at least one chip dummy pad, wherein the plurality of chip pads are attached to the printed circuit board such that the plurality of chip pads face the printed circuit board; and
a plurality of chip terminals comprising
a plurality of chip connection terminals between the plurality of upper connection pads and the plurality of chip connection pads and
at least one chip dummy terminal between the at least one upper monitoring pad and the at least one chip dummy pad,
wherein the at least one upper monitoring pad comprises a base pad portion having the same planar shape as each of the plurality of upper connection pads and a protrusion portion extending in a horizontal direction from the base pad portion.

12. The semiconductor package of claim 11, wherein each of the plurality of chip connection terminals comprises a first under bump metal (UBM) layer covering at least a portion of a lower surface of each of the plurality of chip connection pads, a first conductive pillar attached beneath each of the plurality of chip connection pads and the first UBM layer, and a first conductive cap covering a lower surface of the first conductive pillar,
wherein the at least one chip dummy terminal comprises a second UBM layer covering at least a portion of a lower surface of the at least one chip dummy pad, a second conductive pillar attached beneath the at least one chip dummy pad and the second UBM layer, and a second conductive cap covering a lower surface of the second conductive pillar, and
wherein the first conductive cap covers an upper surface of a corresponding upper connection pad, and the second conductive cap covers an upper surface of the at least one upper monitoring pad.

13. The semiconductor package of claim 12, wherein a maximum horizontal width of the second conductive cap is greater than a maximum horizontal width of the first conductive cap.

14. The semiconductor package of claim 13, wherein the maximum horizontal width of the second conductive cap is the same as a maximum horizontal width of the at least one upper monitoring pad.

15. The semiconductor package of claim 12, wherein the at least one upper monitoring pad comprises a plurality of protrusion portions, and the second conductive cap fully covers respective upper surfaces of the base pad portion and the plurality of protrusion portions in the at least one upper monitoring pad.

16. The semiconductor package of claim 11, wherein each upper connection pad has a first horizontal width, the base pad portion has a second horizontal width equal to the first horizontal width, and the protrusion portion has an extension length that is less than the second horizontal width.

17. The semiconductor package of claim 11, wherein the at least one upper monitoring pad comprises a plurality of upper monitoring pads, the at least one chip dummy pad comprises a plurality of chip dummy pads, and the at least one chip dummy terminal comprises a plurality of chip dummy terminals, and the plurality of upper monitoring pads are 4 or more, the plurality of chip dummy pads and the plurality of chip dummy terminals are a same number as the plurality of upper monitoring pads, and the plurality of upper monitoring pads are arranged adjacent to four corners of the printed circuit board in a top view.

18. A semiconductor package comprising:
a printed circuit board comprising
a substrate base,
an upper solder resist layer covering an upper surface of the substrate base,
a lower solder resist layer covering a lower surface of the substrate base,
a plurality of upper pads on the upper surface of the substrate base, wherein a first portion of each of the plurality of upper pads is covered by the upper solder layer and wherein a second portion of each of the plurality of upper pads is not covered by the upper solder resist layer, and the second portion comprises a plurality of upper connection pads and a plurality of upper monitoring pads,
a plurality of lower connection pads beneath the lower surface of the substrate base and wherein the plurality of lower connection pads are formed by those portions of the lower surface free from the lower solder resist layer, and
a substrate wiring structure electrically connecting the plurality of upper connection pads to the plurality of lower connection pads;
a semiconductor chip comprising
a semiconductor substrate,
a semiconductor device formed on or in the semiconductor substrate,
a plurality of chip pads beneath a lower surface of the semiconductor substrate and comprising a plurality of chip connection pads electrically connected to the semiconductor device, and
a plurality of chip dummy pads electrically isolated from the semiconductor device,
wherein the semiconductor chip is attached to the printed circuit board such that the plurality of chip pads face the printed circuit board; and
a plurality of chip terminals comprising
a plurality of chip connection terminals between the plurality of upper connection pads and the plurality of chip connection pads and
a plurality of chip dummy terminals between the plurality of upper monitoring pads and the plurality of chip dummy pads,
wherein each of the plurality of chip connection terminals and the plurality of chip dummy terminals comprises
an under bump metal (UBM) layer covering at least a portion of a lower surface of a chip pad,
a conductive pillar attached beneath the chip pad and the UBM layer, and
a conductive cap covering a lower surface of the conductive pillar and fully covering upper surfaces of the plurality of upper connection pads and of the plurality of upper monitoring pads,
wherein each of the plurality of upper monitoring pads comprises a base pad portion having the same planar shape as each of the plurality of upper connection pads and a plurality of protrusion portions extending in a horizontal direction from the base pad portion.

19. The semiconductor package of claim 18, wherein each upper connection pad has the same horizontal width as the base pad portion, and a maximum horizontal width of the conductive cap in each chip dummy terminal is greater than a maximum horizontal width of the conductive cap in each chip connection terminal.

20. The semiconductor package of claim 18, wherein a horizontal width of each of the plurality of upper connection pads and the base pad portion is about 40 μm to about 80 μm, and an extension length of each of the plurality of protrusion portions is about 5 μm to about 25 μm.
